(19) United States
(12) Patent Application Publication
(10) Pub. No.: US 2026/0165006 A1
(43) Pub. Date: Jun. 11, 2026

(54) DISPLAY DEVICE

(71) Applicant: LG Display Co., Ltd., Seoul (KR)

(72) Inventors: JongHyun PARK, Paju-si (KR); SangMoo SONG, Seoul (KR)

(73) Assignee: LG Display Co., Ltd., Seoul (KR)

(21) Appl. No.: 19/197,558

(22) Filed: May 2, 2025

(30) Foreign Application Priority Data
Dec. 6, 2024 (KR) 10-2024-0180177

(51) Int. Cl. H10K 59/80; H10H 29/49; H10H 29/855; H10K 59/131

(52) U.S. Cl. CPC H10K 59/879; H10H 29/49; H10H 29/855; H10K 59/131

(57) ABSTRACT

A display device is provided. The display device comprises a substrate, a first light-emitting element on the substrate, and a first optical member configured to refract light emitted from the first light-emitting element. The first optical member has a planar shape that is a shape extending in a first direction to control the distribution of emitted light. The display device further comprises a second light-emitting element on the substrate and configured to emit light of the same color as the light from the first light-emitting element. A second optical member is configured to refract light emitted from the second light-emitting element. The second optical member has a planar shape that extends in a second direction different from the first direction. By employing optical members with directionally distinct planar shapes, the display device can selectively control the viewing angle and improve visibility and privacy depending on user context or operating mode.

### CROSS-REFERENCE TO RELATED APPLICATIONS

This application claims the priority of Korean Patent Application No. 10-2024-0180177 filed on Dec. 6, 2024, in the Korean Intellectual Property Office, the disclosure of which is incorporated herein by reference.

### TECHNICAL FIELD

The present disclosure relates to a display device, and more particularly, to a display device capable of controlling a viewing angle.

### DESCRIPTION OF THE RELATED ART

With the advancement of technologies in the modern society, display devices are being used in various ways to provide information to users. The display devices may be included in electronic display boards, which simply transfer visual information in one direction, and also included in various high-technology electronic devices that identify user inputs and provide information in response to the identified inputs.

For example, the display device may be included in a vehicle and provide various information to a driver and a fellow passenger in the vehicle. However, the display device in the vehicle is required to appropriately display content so as not to hinder the operation of the vehicle. For example, the display device needs to restrict a display of content that may decrease the driver's concentration on driving while the vehicle travels.

### BRIEF SUMMARY

The disclosed display device features a novel dual-mode viewing angle control system that employs two light-emitting elements of the same color within each subpixel, each paired with differently oriented optical members. The first optical member extends horizontally to enable a wide viewing angle (“share mode”), while the second optical member extends vertically to restrict lateral light diffusion and enable a narrow viewing angle (“private mode”). A pixel circuit selectively activates one of the light-emitting elements based on user input or context, allowing real-time switching between shared and private viewing zones.

This structure enables enhanced display functionality, particularly in applications such as vehicle dashboards, where it can reduce or minimize driver distraction by restricting content visibility to passengers. Additional design features, including directionally placed barrier layers, black matrices to prevent color mixing, and protective films with optimized refractive indices, enhance luminance control, ensure content privacy, and improve overall energy efficiency.

Various embodiments of the present disclosure provide a display device capable of reducing a luminance difference caused by a difference between upward and downward viewing angles.

Various embodiments of the present disclosure provide a display device capable of improving visibility of a displayed image regardless of a viewer's eye height.

Various embodiments of the present disclosure provide a display device capable of improving a lifespan of a light-emitting element.

Technical problems of the present disclosure are not limited to the aforementioned technical problems, and other technical problems, which are not mentioned above, may be clearly understood by those skilled in the art from the following descriptions.

The display device according to an example embodiment of the present disclosure comprise a substrate, a first light-emitting element disposed on the substrate, a first optical member configured to refract light emitted from the first light-emitting element, the first optical member having a planar shape that is a shape extending in a first direction, a second light-emitting element disposed on the substrate and configured to emit light with the same color as the light from the first light-emitting element, and a second optical member configured to refract light emitted from the second light-emitting element, the second optical member having a planar shape that is a shape extending in a second direction different from the first direction.

The display device according to an another embodiment of the present disclosure comprises a plurality of subpixels, each of the plurality of subpixels comprising first and second light-emitting elements, the first and second light-emitting elements being configured to emit light with the same color, a first optical member disposed on the first light-emitting element, configured to overlap the first light-emitting element, and disposed to extend in a horizontal direction in a plan view, a second optical member disposed on the second light-emitting element, configured to overlap the second light-emitting element, and disposed to extend in a vertical direction in a plan view, and a subpixel circuit electrically connected to the first and second light-emitting elements and configured to selectively operate at least one of the first and second light-emitting elements. A display device, according to a still another embodiment of the preset disclosure, comprises: a display panel, extending in a first direction and a second direction different from the first direction, comprising a plurality of pixels; wherein each subpixel of one of the plurality of pixels comprises: a first light-emitting element; a plurality of first optical members each of which is configured to refract light emitted from the first light-emitting element, and has a planar shape with a dimension in the first direction greater than a dimension in the second direction; a second light-emitting element configured to emit light with the same color as the light from the first light-emitting element; and a plurality of second optical members each of which is configured to refract light emitted from the second light-emitting element, and has a planar shape with a dimension in the first direction less than a dimension in the second direction.

Other detailed matters of the exemplary embodiments are included in the detailed description and the drawings.

The display device according to the embodiment of the present disclosure includes the optical member having the planar shape extending in the vertical direction, thereby reducing a luminance deviation caused by a difference between the upward and downward viewing angles.

In addition, the display device according to the embodiment of the present disclosure includes the plurality of optical members having different planar shapes, thereby providing high-quality displayed images at various viewing angles.

In addition, the display device according to the embodiment of the present disclosure includes the optical member having the planar shape extending in the vertical direction, thereby improving the luminous efficiency and providing high-quality displayed images with lower electric power.

The effects according to the present disclosure are not limited to the contents exemplified above, and more various effects are included in the present disclosure.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is an exemplified view of a display device according to an embodiment of the present disclosure;

FIG. 2 is a functional block diagram of the display device according to the embodiment of the present disclosure;

FIG. 3 is a circuit diagram illustrating an example of a pixel circuit included in the display device in FIG. 2;

FIG. 4 is an enlarged top plan view illustrating a disposition of an optical member included in the display device according to the embodiment of the present disclosure;

FIG. 5 is a cross-sectional view illustrating an example taken along line V-V′ in FIG. 4;

FIG. 6 is a cross-sectional view illustrating an example taken along line VI-VI′ in FIG. 4;

FIG. 7 is a cross-sectional view illustrating an example taken along line VII-VII′ in FIG. 4;

FIG. 8 is an enlarged top plan view illustrating a disposition of an optical member included in a display device according to another embodiment of the present disclosure;

FIG. 9 is a cross-sectional view illustrating an example taken along line IX-IX′ in FIG. 8;

FIG. 10 is an enlarged top plan view illustrating a disposition of an optical member included in a display device according to still another embodiment of the present disclosure;

FIG. 11 is a cross-sectional view illustrating an example taken along line XI-XI′ in FIG. 10;

FIG. 12 is an enlarged top plan view illustrating a disposition of an optical member included in a display device according to yet another embodiment of the present disclosure;

FIG. 13 is a cross-sectional view illustrating an example taken along line XIII-XIII′ in FIG. 12;

FIG. 14 is a graph for explaining relative luminance in accordance with viewing angles in a leftward/rightward direction of display devices according to Examples of the present disclosure and Comparative Example; and

FIG. 15 is a graph for explaining relative luminance in accordance with viewing angles in an upward/downward direction of the display devices according to Examples of the present disclosure and Comparative Example.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the disclosure. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

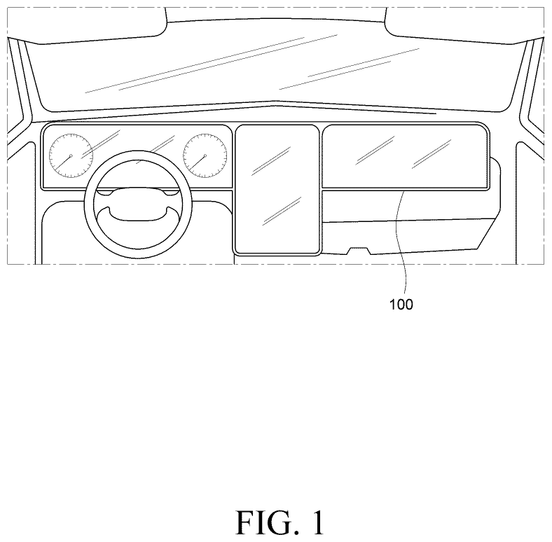

FIG. 1 is an exemplified view illustrating a display device according to an embodiment of the present disclosure.

With reference to FIG. 1, a display device 100 may be disposed on at least a part of a dashboard of a vehicle. The dashboard of the vehicle may include a configuration disposed at a front side of a front seat (e.g., a driver seat or a passenger seat) of the vehicle. For example, the dashboard of the vehicle may be equipped with an input configuration for manipulating various functions (e.g., an air conditioner, an audio system, and a navigation system) in the vehicle.

The display device 100 may be disposed on the dashboard of the vehicle and operate as an input part for manipulating at least some of various functions of the vehicle. The display device 100 may provide various types of information related to the vehicle, e.g., driving information of the vehicle (e.g., a current speed of the vehicle, a remaining fuel amount, and a traveling distance), information on components of the vehicle (e.g., a degree of damage to a vehicle tire), and the like.

The display device 100 may be disposed to traverse the driver seat and the passenger seat disposed as the front seat of the vehicle. Users of the display device 100 may include a driver of the vehicle, and a fellow passenger seated in the passenger seat. Both the driver and the fellow passenger in the vehicle may use the display device 100.

Only a part of the display device 100 may be illustrated in FIG. 1. The display device 100 illustrated in FIG. 1 may be illustrated as a display panel among various components included in the display device 100. Specifically, for example, the display device 100 illustrated in FIG. 1 may be illustrated as at least a part of a display area and at least a part of a non-display area of the display panel. The components, which exclude the components illustrated in FIG. 1 among the components of the display device 100, may be mounted in the vehicle (or at least a part of the vehicle).

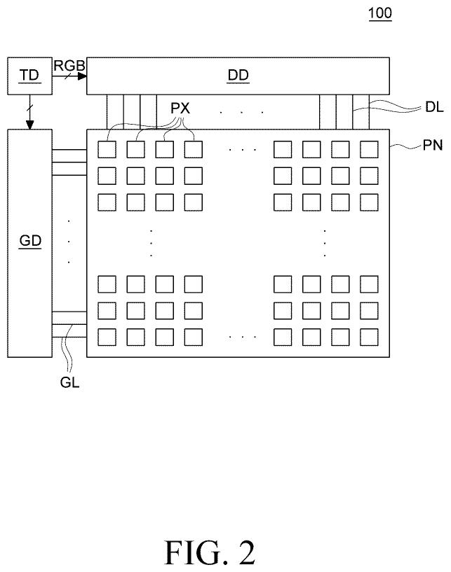

FIG. 2 is a functional block diagram of the display device according to the embodiment of the present disclosure.

An electroluminescent display device may be applied as the display device according to the embodiment of the present disclosure. An organic light-emitting diode display device, a quantum-dot light-emitting diode display device, or an inorganic light-emitting diode display device may be used as the electroluminescent display device.

With reference to FIG. 2, the display device 100 may include a display panel PN, a data drive circuit DD, a gate drive circuit GD, and a timing controller TD.

The display panel PN may create an image to be provided to the user. For example, the display panel PN may create and display images, which are to be provided to the user, through a plurality of pixels PX in which pixel circuits are disposed.

The data drive circuit DD, the gate drive circuit GD, and the timing controller TD may provide signals for operating the pixels PX through signal lines. For example, the signal lines for providing the signals for operating the pixels PX may include the plurality of data lines DL and the plurality of gate lines GL.

The plurality of data lines DL may include a plurality of lines arranged in a column direction and connected to the pixels PX disposed in one column direction. The plurality of gate lines GL may include a plurality of lines arranged in a row direction and connected to the pixels PX disposed in one row direction.

In some instances, the display device 100 may further include a power source unit. In this case, the signal for operating the pixel PX may be provided through a power line that connects the power source unit and the display panel PN. According to the embodiment, the power source unit may provide power to the data drive circuit DD and the gate drive circuit GD. The data drive circuit DD and the gate drive circuit GD may operate on the basis of power provided from the power source unit.

For example, the data drive circuit DD may apply data signals to the pixels PX through the plurality of data lines DL, the gate drive circuit GD may apply gate signals to the pixels PX through the plurality of gate lines GL, and the power source unit may supply power voltages to the pixels PX through power voltage supply lines.

The timing controller TD may control the data drive circuit DD and the gate drive circuit GD. For example, the timing controller TD may realign digital video data, which are inputted from the outside, to fit the resolution of the display panel PN and supply the video data to the data drive circuit DD.

The data drive circuit DD may convert digital video data, which are inputted from the timing controller TD, into analog data voltage on the basis of a data control signal and supply the analog data voltage to the plurality of data lines DL.

The gate drive circuit GD may generate a scan signal and a light emission signal in response to the gate control signal. For example, the gate drive circuit GD may include a scan driver and a light emission signal driver. The scan driver may generate scan signals in a row-sequential manner to operate at least one scan line connected to each pixel row and supply the scan signals to scan lines. The light emission signal driver may generate light emission signals in a row-sequential manner to operate at least one light emission signal line connected to each pixel row and supply the light emission signals to light emission signal lines.

According to the embodiment, the gate drive circuit GD may be disposed on the display panel PN in a gate-driver-in-panel (GIP) manner. For example, the gate drive circuit GD may be divided into a plurality of gate drive circuits and respectively disposed on at least two side surface of the display panel PN.

The display panel PN may include a display area and a non-display area configured to surround the display area.

The display area of the display panel PN may include the plurality of pixels PX disposed in the row direction and the column direction. For example, the plurality of pixels PX may be disposed in an area in which the plurality of data lines DL and the plurality of gate lines GL intersect.

One pixel PX may include a plurality of subpixels that emit light beams with different colors. For example, one pixel PX may implement blue, red, and green by using three subpixels. However, the present disclosure is not limited thereto. In some instances, the pixel PX may further include a subpixel for further implementing a particular color, e.g., white.

In the pixel PX, the area for implementing blue may be referred to as a blue subpixel, an area for implementing red may be referred to as a red subpixel, and an area for implementing green may be referred to as a green subpixel.

The plurality of pixels PX may each include first and second light-emitting elements that emit light with the same color.

The plurality of pixels PX may each include a first optical member configured to refract the light, which is emitted from the first light-emitting element, in a particular direction, and a second optical member configured to refract the light, which is emitted from the second light-emitting element, in a particular direction. For example, the first and second optical members may each be implemented as a lens. However, the embodiment of the present disclosure is not limited thereto.

For example, the first optical member may be disposed in an optical area configured to define a first viewing angle by providing light in a first range, and the second optical member may be disposed in an optical area configured to define a second viewing angle by providing light in a second range. The first range may correspond to a range larger than the second range. Therefore, the first and second optical members may restrict the viewing angle of the each of plurality of pixels PX.

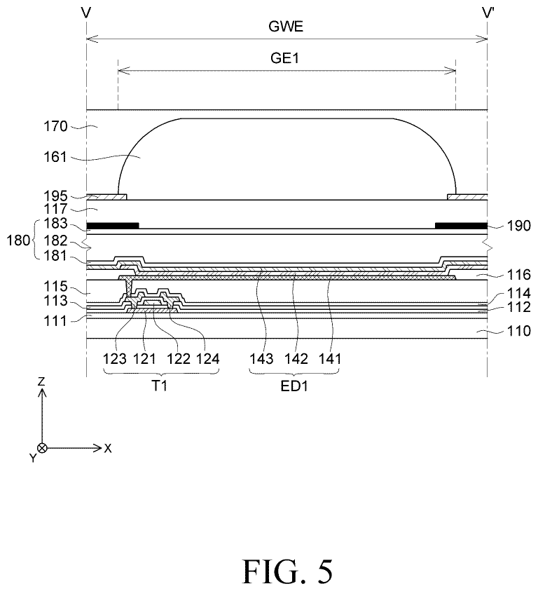

The first and second optical members will be described below in detail with reference to FIGS. 5 to 7.

The non-display area may be disposed along a periphery of the display area. Various constituent elements for operating the pixel circuit disposed in the pixel PX may be disposed in the non-display area. For example, at least a part of the gate drive circuit GD may be disposed in the non-display area. The non-display area may be referred to as a bezel area.

When the display panel PN is used for the vehicle described with reference to FIG. 1, a visual field of at least some areas of the display panel PN is required to be restricted in response to the user's needs. For example, the image, which is displayed in the area that provides the entertainment function, seat information, and the like for the fellow passenger seated in the passenger seat in the display area of the display panel PN, may hinder the driver who drives the vehicle. Therefore, the visual field of the image displayed in the corresponding area may sometimes be required to be restricted in response to the user's needs.

Therefore, the pixels PX included in the display panel PN may each be operated in a first or second mode depending on a drive mode. For example, in case that the pixel PX operates in the first mode, the first light-emitting element included in the pixel PX may emit light in response to a selection signal, and the light emitted from the first light-emitting element is provided in the first range through the first optical member, such that the first viewing angle, e.g., a wide viewing angle may be defined. In addition, in case that the pixel PX operates in the second mode, the second light-emitting element included in the pixel PX may emit light in response to a selection signal, and the light emitted from the second light-emitting element may be provided in the second range through the second optical member, such that the second viewing angle, e.g., a narrow viewing angle may be defined. In this case, the first mode may correspond to a mode in which the corresponding pixel PX is controlled in a wide visual field mode (share mode), and the second mode may correspond to a mode in which the corresponding pixel PX is operated in a narrow visual field mode (private mode).

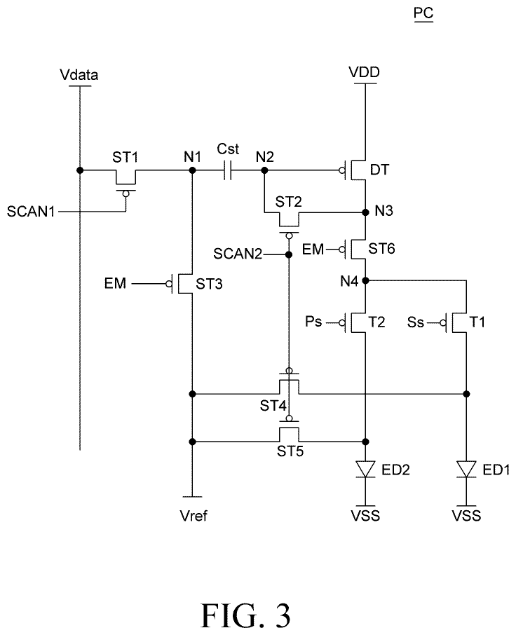

FIG. 3 is a circuit diagram illustrating an example of the pixel circuit included in the display device in FIG. 2.

Meanwhile, a pixel circuit PC illustrated in FIG. 3 represents one embodiment of the pixel circuit corresponding to one subpixel of each of the plurality of pixels PX included in the display device 100 described with reference to FIG. 2. The subpixel comprises first and second light-emitting elements ED1 and ED2 that emit light of the same color.

With reference to FIG. 3, at least some of the plurality of transistors included in the pixel circuit PC may each be an n-type transistor or a p-type transistor. In the case of the p-type transistor, a low-level voltage of each of the driving signals may mean a voltage that turns on the TFT, and a high-level voltage of each of the driving signals may mean a voltage that turns off the TFTs.

In this case, the low-level voltage may correspond to a predesignated voltage lower than the high-level voltage. For example, the low-level voltage may include a voltage corresponding to a range of −8 V to −12 V. The high-level voltage may correspond to a predesignated voltage higher than the low-level voltage. For example, the high-level voltage may include a voltage corresponding to a range of 12 V to 16 V. According to the embodiment, the low-level voltage may be referred to as a first voltage, and the high-level voltage may be referred to as a second voltage. In this case, the first voltage may have a lower value than the second voltage.

The pixel circuit PC may include a driving transistor DT, a plurality of switching transistors ST1, ST2, ST3, ST4, ST5, and ST6, a first transistor T1, a second transistor T2, a storage capacitor Cst, and a plurality of light-emitting elements ED1 and ED2.

The driving transistor DT may control a drive current to be applied to the plurality of light-emitting elements ED1 and ED2 in accordance with a source-gate voltage. The driving transistor DT may include a source electrode connected to the high-potential power line, which provides a high-potential power voltage VDD, a gate electrode connected to a second node N2, and a drain electrode connected to a third node N3.

A first switching transistor ST1 may apply a data voltage Vdata to a first node N1 from a data line DL. The first switching transistor ST1 may include a source electrode connected to the data line DL, a drain electrode connected to the first node N1, and a gate electrode connected to a first scan signal line to which a first scan signal SCAN1 is applied. The first switching transistor ST1 may be turned on or off by the first scan signal SCAN1. Therefore, the first switching transistor ST1 may apply the data voltage Vdata from the data line DL to the first node N1 in response to the first scan signal SCAN1 at a low level, i.e., a turn-on level.

A second switching transistor ST2 may diode-connect the gate electrode and the drain electrode of the driving transistor DT. The second switching transistor ST2 may include a drain electrode connected to the second node N2, a source electrode connected to the third node N3, and a gate electrode connected to a second scan signal line to which a second scan signal SCAN2 is applied. The second switching transistor ST2 may be turned on or off by the second scan signal SCAN2. Therefore, the second switching transistor ST2 may diode-connect the gate electrode and the drain electrode of the driving transistor DT in response to the second scan signal SCAN2 at a low level, i.e., a turn-on level.

A third switching transistor ST3 may apply a reference voltage Vref to the first node N1. The third switching transistor ST3 may include a source electrode connected to a reference voltage line configured to provide the reference voltage Vref, a drain electrode connected to the first node N1, and a gate electrode connected to a light emission signal line to which a light emission signal EM is applied. The third switching transistor ST3 may be turned on or off by the light emission signal EM. Therefore, the third switching transistor ST3 may transmit the reference voltage Vref to the first node N1 in response to the light emission signal EM at a low level, i.e., a turn-on level.

A fourth switching transistor ST4 may apply the reference voltage Vref to an anode electrode of a first light-emitting element ED1. The fourth switching transistor ST4 may include a source electrode connected to the reference voltage line configured to provide the reference voltage Vref, a drain electrode connected to the anode electrode of the first light-emitting element ED1, and a gate electrode connected to the second scan signal line to which the second scan signal SCAN2 is applied. The fourth switching transistor ST4 may be turned on or off by the second scan signal SCAN2. Therefore, the fourth switching transistor ST4 may apply the reference voltage Vref to the anode electrode of the first light-emitting element ED1 in response to the second scan signal SCAN2 at a low level, i.e., a turn-on level.

A fifth switching transistor ST5 may apply the reference voltage Vref to an anode electrode of a second light-emitting element ED2. The fifth switching transistor ST5 may include a source electrode connected to the reference voltage line configured to provide the reference voltage Vref, a drain electrode connected to the anode electrode of the second light-emitting element ED2, and a gate electrode connected to the second scan signal line to which the second scan signal SCAN2 is applied. The fifth switching transistor ST5 may be turned on or off by the second scan signal SCAN2. Therefore, the fifth switching transistor ST5 may apply the reference voltage Vref to the anode electrode of the second light-emitting element ED2 in response to the second scan signal SCAN2 at a low level, i.e., a turn-on level.

A sixth switching transistor ST6 may form a current path between the driving transistor DT and any one of the plurality of light-emitting elements ED1 and ED2. The sixth switching transistor ST6 may include a source electrode connected to the third node N3, a drain electrode connected to a fourth node N4, and a gate electrode connected to a light-emitting signal line to which the light emission signal EM is applied. The sixth switching transistor ST6 may be turned on or off by the light emission signal EM. Therefore, the sixth switching transistor ST6 may form the current path between the driving transistor DT and any one of the plurality of light-emitting elements ED1 and ED2 by electrically connecting the third node N3 and the fourth node N4 in response to the light emission signal EM at a low level, i.e., a turn-on level.

The storage capacitor Cst may include a first electrode connected to the first node N1, and a second electrode connected to the second node N2. One electrode of the storage capacitor Cst may be connected to the gate electrode of the driving transistor DT, and another electrode of the storage capacitor Cst may be connected to the first switching transistor ST1. The storage capacitor Cst may store a predetermined voltage and maintain a predetermined voltage of the gate electrode of the driving transistor DT while any one of the plurality of light-emitting elements ED1 and ED2 emits light.

The first transistor T1 may create a current path for a first drive current passing through the first light-emitting element ED1, and the second transistor T2 may create a current path for a second drive current passing through the second light-emitting element ED2.

The first transistor T1 may be connected between the fourth node N4 and the first light-emitting element ED1, and a gate electrode of the first transistor T1 may be connected to a first selection signal line configured to provide a first selection signal Ss. When the pixel PX to which the pixel circuit PC is applied operates in the first mode that is the wide visual field mode, the first selection signal Ss may be supplied to the gate electrode of the first transistor T1, such that the first transistor T1 may be turned on. Therefore, the current path for the first drive current passing through the first light-emitting element ED1 is formed, such that the first light-emitting element ED1 may emit light. Meanwhile, the first transistor T1 may be referred to as a first light emission control transistor configured to control the light emission from the first light-emitting element ED1.

The second transistor T2 may be connected between the fourth node N4 and the second light-emitting element ED2, and a gate electrode of the second transistor T2 may be connected to a second selection signal line configured to provide a second selection signal Ps. When the pixel PX to which the pixel circuit PC is applied operates in the second mode that is the narrow visual field mode, the second selection signal Ps may be supplied to the gate electrode of the second transistor T2, such that the second transistor T2 may be turned on. Therefore, the current path for the second drive current passing through the second light-emitting element ED2 is formed, such that the second light-emitting element ED2 may emit light. Meanwhile, the second transistor T2 may be referred to as a second light emission control transistor configured to control the light emission from the second light-emitting element ED2.

The first light-emitting element ED1 may be connected between the first transistor T1, which is turned on or off by the first selection signal Ss, and a low-potential power line configured to provide a low-potential power voltage VSS. The second light-emitting element ED2 may be connected between the second transistor T2, which is turned on or off by the second selection signal Ps, and the low-potential power line configured to provide the low-potential power voltage VSS.

In this case, the first light-emitting element ED1 or the second light-emitting element ED2 may be connected to another component of the pixel circuit PC, e.g., the driving transistor DT by the first transistor T1 or the second transistor T2 that is turned on in accordance with the drive mode. For example, the first light-emitting element ED1 may be connected to the driving transistor DT through the first transistor T1, which is turned on in the first mode, and provide the light at the wide viewing angle, which is the first viewing angle, in the first mode, i.e., the wide visual field mode by the first drive current. In addition, the second light-emitting element ED2 may be connected to the driving transistor DT through the second transistor T2, which is turned on in the second mode, and provide the light at the narrow viewing angle, which is the second viewing angle, in the second mode, i.e., the narrow visual field mode by the second drive current. In this case, the drive mode may be determined in case that a condition, which is designated by the user's input or designated in advance, is satisfied.

Only the first light-emitting element ED1 may emit light in the first mode, and only the second light-emitting element ED2 may emit light in the second mode. In this case, in the first mode, the second selection signal Ps for controlling the light emission from the second light-emitting element ED2 may be outputted only at a high level, i.e., a turn-off level so that only the first light-emitting element ED1 emits light. In addition, in the second mode, the first selection signal Ss for controlling the light emission from the first light-emitting element ED1 may be outputted only at a high level, i.e., a turn-off level so that only the second light-emitting element ED2 emits light.

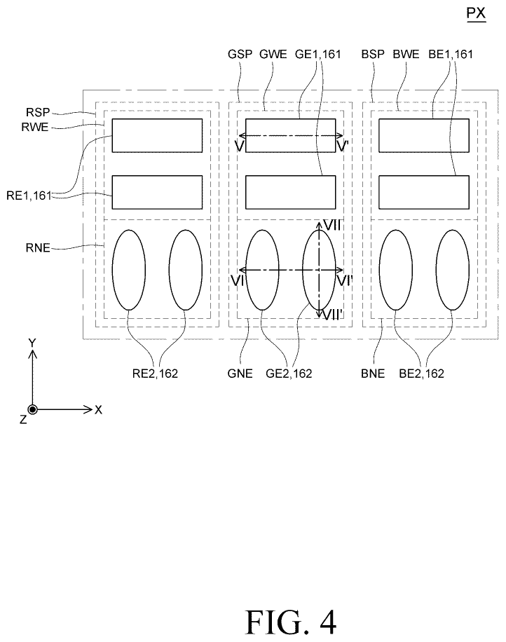

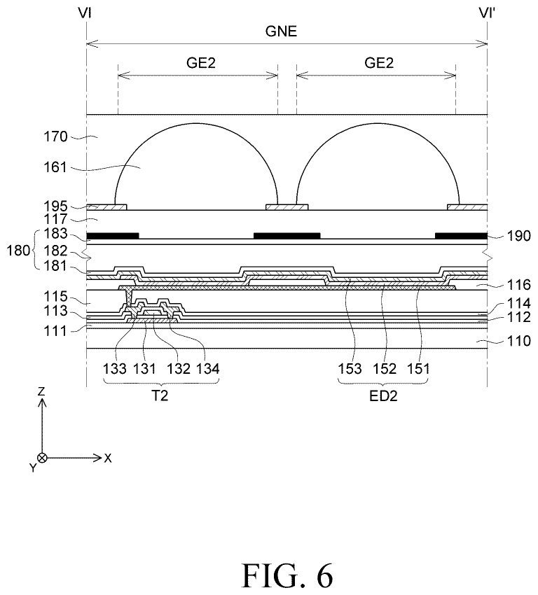

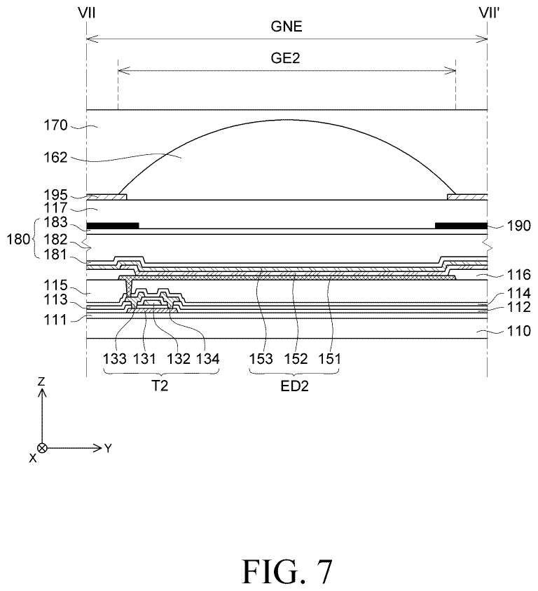

FIG. 4 is an enlarged top plan view illustrating a disposition of the optical member included in the display device according to the embodiment of the present disclosure. FIG. 5 is a cross-sectional view illustrating an example taken along line V-V′ in FIG. 4. FIG. 6 is a cross-sectional view illustrating an example taken along line VI-VI′ in FIG. 4. FIG. 7 is a cross-sectional view illustrating an example taken along line VII-VII′ in FIG. 4.

Meanwhile, FIG. 4 illustrates a plane of the pixel PX in case that the pixel PX includes three subpixels, e.g., a first subpixel RSP, a second subpixel GSP, and a third subpixel BSP. In addition, FIG. 5 is a view illustrating a pixel in which a first optical member 161 is disposed in the embodiment of the display device 100 taken along line V-V′ in FIG. 4, and FIG. 6 is a view illustrating a pixel in which a second optical member 162 is disposed in the embodiment of the display device 100 taken along line VI-VI′ in FIG. 4. In addition, FIG. 7 is a view illustrating the pixel in which the second optical member 162 is disposed in the embodiment of the display device 100 taken along line VII-VII′ in FIG. 4.

Meanwhile, for convenience of description, FIGS. 5 to 7 illustrate only an area corresponding to a first optical area GWE and a second optical area GNE of the second subpixel GSP among the three subpixels RSP, GSP, and BSP illustrated in FIG. 4. However, the same configuration may also be applied to the other subpixels RSP and BSP.

Meanwhile, for convenience of description, hereinafter, a first direction X is illustrated as a horizontal direction in a plan view, and a second direction Y is illustrated as a vertical direction in a plan view. In addition, a normal direction to a plane defined by the first direction X and the second direction Y, e.g., a thickness direction of the display device 100 may be defined as a third direction Z.

With reference to FIG. 4, the pixel PX may include the plurality of subpixels RSP, GSP, and BSP that displays different colors. For example, the pixel PX may include the first subpixel RSP configured to implement red, the second subpixel GSP configured to implement green, and the blue subpixel BSP configured to implement blue. According to the embodiment, the first subpixel RSP may be referred to as a red subpixel, the second subpixel GSP may be referred to as a green subpixel, and the third subpixel BSP may be referred to as a blue subpixel. The pixel circuit PC, which has been described with reference to FIG. 3, may be disposed in each of the plurality of subpixels RSP, GSP, and BSP included in the pixel PX.

The plurality of subpixels RSP, GSP, and BSP may respectively include first optical areas RWE, GWE, and BWE and second optical areas RNE, GNE, and BNE configured to provide different viewing angles.

The first optical areas RWE, GWE, and BWE of the subpixels RSP, GSP, and BSP may operate independently of the second optical areas RNE, GNE, and BNE of the corresponding pixel PX. For example, the subpixels RSP, GSP, and BSP may respectively include the first light-emitting elements ED1 disposed in the first optical areas RWE, GWE, and BWE of the corresponding subpixels RSP, GSP, and BSP, and the second light-emitting elements ED2 disposed in the second optical areas RNE, GNE, and BNE of the corresponding subpixels RSP, GSP, and BSP.

In one pixel PX, the first light-emitting element ED1 and the second light-emitting element ED2 may be disposed in each of the first optical areas RWE, GWE, and BWE and the second optical areas RNE, GNE, and BNE of the plurality of subpixels RSP, GSP, and BSP.

For example, one pixel PX may include the first light-emitting element ED1 disposed in the first optical area RWE of the first subpixel RSP, the second light-emitting element ED2 disposed in the second optical area RNE of the first subpixel RSP, the first light-emitting element ED1 disposed in the first optical area GWE of the second subpixel GSP, the second light-emitting element ED2 disposed in the second optical area GNE of the second subpixel GSP, the first light-emitting element ED1 disposed in the first optical area BWE of the third subpixel BSP, and the second light-emitting element ED2 disposed in the second optical area BNE of the third subpixel BSP.

In addition, the first optical areas RWE, GWE, and BWE of the plurality of subpixels RSP, GSP, and BSP may include a plurality of first light-emitting areas RE1, GE1, and BE1. In addition, the second optical areas RNE, GNE, and BNE of the plurality of subpixels RSP, GSP, and BSP may include a plurality of second light-emitting areas RE2, GE2, and BE2.

For example, the first optical area RWE of the first subpixel RSP may include two or more first light-emitting areas RE1. Further, the second optical area RNE may include two or more second light-emitting areas RE2. In addition, two or more first light-emitting areas GE1 may be disposed in the first optical area GWE of the second subpixel GSP, and two or more second light-emitting areas GE2 may be disposed in the second optical area GNE. Next, two or more first light-emitting areas BE1 may be disposed in the first optical area BWE of the third subpixel BSP, and two or more second light-emitting areas BE2 may be disposed in the second optical area BNE.

With reference to FIG. 4, at least one first optical member 161 may be disposed in each of the first optical areas RWE, GWE, and BWE of the subpixels RSP, GSP, and BSP and disposed to overlap each of the first light-emitting areas RE1, GE1, and BE1 of the first light-emitting element ED1. At least one second optical member 162 may be disposed in each of the second optical areas RNE, GNE, and BNE of the subpixels RSP, GSP, and BSP and disposed to overlap each of the second light-emitting areas RE2, GE2, and BE2 of the second light-emitting element ED2. Therefore, in case that the first light-emitting areas RE1, GE1, and BE1 and the second light-emitting areas RE2, GE2, and BE2 disposed in the subpixels RSP, GSP, and BSP are the plurality of first light-emitting areas RE1, GE1, and BE1 and the plurality of second light-emitting areas RE2, GE2, and BE2, the plurality of first optical members 161 and the plurality of second optical members 162 may also be provided correspondingly.

In this case, in case that the plurality of first optical members 161 are disposed in the subpixels RSP, GSP, and BSP, the plurality of first optical members 161 disposed in the subpixels RSP, GSP, and BSP may be spaced apart from one another in the second direction Y in a plan view. For example, in case that two first optical members 161 are disposed in the first optical area RWE of the first subpixel RSP, the plurality of first optical members 161 may be disposed to be spaced apart from one another on a straight line extending in the second direction Y. In this case, in the subpixels RSP, GSP, and BSP, the plurality of first optical members 161 may overlap one another in the second direction Y. However, the present disclosure is not limited thereto.

In addition, the first optical members 161 disposed in the subpixels RSP, GSP, and BSP adjacent to one another may be disposed on a straight line extending in the first direction X in a plan view. For example, the first optical member 161 of the second subpixel GSP may be disposed in the same row as the first optical member 161 disposed in the first subpixel RSP. In addition, the first optical member 161 of the third subpixel BSP may be disposed in the same row as the first optical member 161 of the second subpixel GSP.

In case that the plurality of second optical members 162 are disposed in the subpixels RSP, GSP, and BSP, the plurality of second optical members 162 disposed in the subpixels RSP, GSP, and BSP may be spaced apart from one another in the first direction X in a plan view. For example, in case that two second optical members 162 are disposed in the second optical area RNE of the first subpixel RSP, the plurality of second optical members 162 may be disposed to be spaced apart from each other on a straight line extending in the first direction X. In this case, in the subpixels RSP, GSP, and BSP, the plurality of second optical members 162 may overlap one another in the first direction X. However, the present disclosure is not limited thereto.

The second optical members 162 disposed in the subpixels RSP, GSP, and BSP adjacent to one another may be disposed on a straight line extending in the first direction X in a plan view. In addition, at least some of the second optical members 162 may overlap the first optical members 161 in the second direction Y. However, the present disclosure is not limited thereto.

With reference to FIGS. 4 to 7 together, the display device 100 according to the embodiment of the present disclosure may include a substrate 110, a buffer film 111, a gate insulation film 112, an interlayer insulation film 113, a lower protective film 114, an overcoating layer 115, a bank 116, the first transistor T1, the second transistor T2, the first light-emitting element ED1, the second light-emitting element ED2, an encapsulation member 180, a touch insulation layer 117, a black matrix 190, barrier layers 195, the first optical member 161, the second optical member 162, and an optical member protective film 170.

The substrate 110 may include an insulating material. The substrate 110 may include a transparent material. For example, the substrate 110 may include glass or plastic.

The buffer film 111 may be disposed on the substrate 110. The buffer film 111 may include an insulating material. For example, the buffer film 111 may include an inorganic insulating material such as silicon oxide (SiOx) and silicon nitride (SiNx). The buffer film 111 may have a multilayer structure. For example, the buffer film 111 may have a stacked structure including a film made of silicon nitride (SiNx) and a film made of silicon oxide (SiOx).

The buffer film 111 may be positioned between the substrate 110 and a drive part of each of the subpixels RSP, GSP, and BSP. The buffer film 111 may suppress contamination caused by the substrate 110 during a process of forming the drive part. For example, a top surface of the substrate 110, which is directed toward the drive part of each of the subpixels RSP, GSP, and BSP, may be covered by the buffer film 111. The drive part of each of the subpixels RSP, GSP, and BSP may be positioned on the buffer film 111.

The gate insulation film 112 may be disposed on the buffer film 111. The gate insulation film 112 may include an insulating material. For example, the gate insulation film 112 may include an inorganic insulating material such as silicon oxide (SiO) and silicon nitride (SiN). The gate insulation film 112 may include a material having high permittivity. For example, the gate insulation film 112 may include a high-K material such as hafnium oxide (HfO). The gate insulation film 112 may have a multilayer structure.

The interlayer insulation film 113 may be disposed on the gate insulation film 112. The interlayer insulation film 113 may include an insulating material. For example, the interlayer insulation film 113 may include an inorganic insulating material such as silicon oxide (SiO) and silicon nitride (SiN). The interlayer insulation film 113 may extend between gate electrodes 122 and 132 and source electrodes 123 and 133 of the transistors T1 and T2 and between gate electrodes 122 and 132 and drain electrodes 124 and 134 of the transistors T1 and T2. For example, the source electrodes 123 and 133 and the drain electrodes 124 and 134 of the first transistor T1 and the second transistor T2 may be insulated from the gate electrodes 122 and 132 by the interlayer insulation film 113. The interlayer insulation film 113 may cover the gate electrodes 122 and 132 of the first transistor T1 and the second transistor T2. The source electrodes 123 and 133 and the drain electrodes 124 and 134 of each of the subpixels RSP, GSP, and BSP may be positioned on the interlayer insulation film 113. The gate insulation film 112 and the interlayer insulation film 113 may expose source areas and drain areas of semiconductor layers 121 and 131 positioned in each of the subpixels RSP, GSP, and BSP.

The lower protective film 114 may be disposed on the interlayer insulation film 113. The lower protective film 114 may include an insulating material. For example, the lower protective film 114 may include an inorganic insulating material such as silicon oxide (SiO) and silicon nitride (SiN).

The lower protective film 114 may suppress damage to the drive part caused by external moisture and impact. The lower protective film 114 may extend along surfaces of the first and second transistors T1 and T2. The lower protective film 114 may be in contact with the interlayer insulation film 113 outside the drive part positioned in each of the subpixels RSP, GSP, and BSP.

The overcoating layer 115 may be disposed on the lower protective film 114. The overcoating layer 115 may include an insulating material. The overcoating layer 115 may include a material different from the material of the lower protective film 114. For example, the overcoating layer 115 may include an organic insulating material.

The overcoating layer 115 may remove a level difference caused by the drive part of each of the subpixels RSP, GSP, and BSP. For example, a top surface of the overcoating layer 115, which is opposite to the substrate 110, may be a flat surface.

The first transistor T1 and the second transistor T2 may be disposed on the substrate 110. The first transistor T1 may be electrically connected between the drain electrode of the driving transistor DT and a first lower electrode 141 of the first light-emitting element ED1. The second transistor T2 may be electrically connected between the drain electrode of the driving transistor DT and a second lower electrode 151 of the second light-emitting element ED2.

The first transistor T1 may include a first semiconductor layer 121, a first gate electrode 122, a first source electrode 123, and a first drain electrode 124. The first transistor T1 may have the same structure as the switching transistor and the driving transistor.

For example, the first semiconductor layer 121 may be positioned between the buffer film 111 and the gate insulation film 112, and the first gate electrode 122 may be positioned between the gate insulation film 112 and the interlayer insulation film 113. The first source electrode 123 and the first drain electrode 124 may be positioned between the interlayer insulation film 113 and the lower protective film 114. The first gate electrode 122 may overlap a channel area of the first semiconductor layer 121. The first source electrode 123 may be electrically connected to a source area of the first semiconductor layer 121. The first drain electrode 124 may be electrically connected to a drain area of the first semiconductor layer 121.

The second transistor T2 may include a second semiconductor layer 131, a second gate electrode 132, a second source electrode 133, and a second drain electrode 134. For example, the second semiconductor layer 131 may be positioned on the same layer as the first semiconductor layer 121, the second gate electrode 132 may be positioned on the same layer as the first gate electrode 122, and the second source electrode 133 and the second drain electrode 134 may be positioned on the same layer as the first source electrode 123 and the first drain electrode 124.

The first light-emitting element ED1 and the second light-emitting element ED2 of each of the subpixels RSP, GSP, and BSP may be disposed on the overcoating layer 115 of each of the corresponding subpixels RSP, GSP, and BSP. For example, the first lower electrode 141 of the first light-emitting element ED1 may be electrically connected to the first drain electrode 124 or the first source electrode 123 of the first transistor T1 through contact holes formed through the lower protective film 114 and the overcoating layer 115, and the second lower electrode 151 of the second light-emitting element ED2 may be electrically connected to the second drain electrode 134 or the second source electrode 133 of the second transistor T2 through contact holes formed through the lower protective film 114 and the overcoating layer 115.

The first light-emitting element ED1 may emit light with a particular color. For example, the first light-emitting element ED1 may include the first lower electrode 141, a first light-emitting layer 142, and a first upper electrode 143 sequentially stacked on the substrate 110.

The first lower electrode 141 may include an electrically conductive material. The first lower electrode 141 may include a material having high reflectance. For example, the first lower electrode 141 may include metal such as aluminum (Al) and silver (Ag). The first lower electrode 141 may have a multilayer structure. For example, the first lower electrode 141 may have a structure in which a reflective electrode, which is made of metal, is positioned between transparent electrodes made of a transparent conductive material such as ITO and IZO. The first lower electrode 141 may be electrically connected to the first drain electrode 124 of the first transistor T1 through contact holes formed through the lower protective film 114 and the overcoating layer 115.

The first light-emitting layer 142 may create light with luminance corresponding to a voltage difference between the first lower electrode 141 and the first upper electrode 143. For example, the first light-emitting layer 142 may include an emission material layer (EML) including a light-emitting material. The light-emitting material may include an organic material, an inorganic material, or a hybrid material.

The first light-emitting layer 142 may have a multilayer structure. For example, the first light-emitting layer 142 may further include at least one of a hole injection layer (HIL), a hole transport layer (HTL), an electron transport layer (ETL), and an electron injection layer (EIL).

The first upper electrode 143 may include an electrically conductive material. The first upper electrode 143 may include a material different from the material of the first lower electrode 141. A transmittance rate of the first upper electrode 143 may be higher than a transmittance rate of the first lower electrode 141. For example, the first upper electrode 143 may be configured as a transparent electrode made of a transparent conductive material such as ITO and IZO. Therefore, in the display device 100 according to the embodiment of the present disclosure, the light created by the first light-emitting layer 142 may be discharged through the first upper electrode 143.

The second light-emitting element ED2 may implement the same color as the first light-emitting element ED1 disposed in the same subpixels RSP, GSP, and BSP. For example, the second light-emitting element ED2 may include the second lower electrode 151, a second light-emitting layer 152, and a second upper electrode 153 sequentially stacked on the substrate 110.

The second lower electrode 151 may correspond to the first lower electrode 141, the second light-emitting layer 152 may correspond to the first light-emitting layer 142, and the second upper electrode 153 may correspond to the first upper electrode 143. For example, the second lower electrode 151 may be formed for the second light-emitting element ED2 while having the same structure as the first lower electrode 141. The same may apply to the second light-emitting layer 152 and the second upper electrode 153. For example, the first light-emitting element ED1 and the second light-emitting element ED2 may be formed to have the same structure. However, the present disclosure is not limited thereto. In some instances, the first light-emitting element ED1 and the second light-emitting element ED2 may be formed to be different from each other in at least some configurations.

The second light-emitting layer 152 may be spaced apart from the first light-emitting layer 142. Therefore, in the display device according to the embodiment of the present disclosure, it is possible to suppress light emission caused by a leakage current.

According to the embodiment of the present disclosure, in the display device, only one of the first light-emitting layer 142 and the second light-emitting layer 152 may create light in accordance with the user's selection or a predesignated condition.

The second lower electrode 151 of each of the subpixels RSP, GSP, and BSP may be spaced apart from the first lower electrode 141 of each of the corresponding subpixels RSP, GSP, and BSP. For example, the bank 116 may be disposed between the first lower electrode 141 and the second lower electrode 151 of each of the subpixels RSP, GSP, and BSP. The bank 116 may include an insulating material. For example, the bank 116 may include an organic insulating material. The bank 116 may include a material different from the material of the overcoating layer 115.

The second lower electrode 151 of each of the subpixels RSP, GSP, and BSP may be insulated from the first lower electrode 141 of each of the corresponding subpixels RSP, GSP, and BSP by the bank 116. For example, the bank 116 may cover an edge of the first lower electrode 141 and an edge of the second lower electrode 151 positioned in each of the subpixels RSP, GSP, and BSP.

The bank 116 may separate the first light-emitting areas RE1, GE1, and BE1 of the first light-emitting element ED1 and the second light-emitting areas RE2, GE2, and BE2 of the second light-emitting element ED2. For example, the first light-emitting areas RE1, GE1, and BE1 of the first light-emitting element ED1 may each be defined as an edge area of the first lower electrode 141 covered by the bank 116. The second light-emitting areas RE2, GE2, and BE2 of the second light-emitting element ED2 may each be defined as an edge area of the second lower electrode 151 covered by the bank 116. In addition, the bank 116 may be stacked on a partial area of the first lower electrode 141 or the second lower electrode 151. Specifically, a top surface of the first lower electrode 141 or the second lower electrode 151 may be divided into at least two areas by the bank 116. With reference to FIG. 6, the top surface of the second lower electrode 151 may be divided into two areas by the bank 116, and the two areas may each correspond to the second light-emitting area GE2. Likewise, the top surface of the first lower electrode 141 may also be divided into two areas by the bank 116, and the two areas may each correspond to the first light-emitting area GE1.

The first light-emitting layer 142 and the first upper electrode 143 of the first light-emitting element ED1 positioned in each of the subpixels RSP, GSP, and BSP may be stacked on a partial area of the corresponding first lower electrode 141 exposed by the bank 116. Specifically, the first light-emitting layer 142 and the first upper electrode 143 may be stacked on the bank 116 and a partial area of the corresponding first lower electrode 141 exposed by the bank 116. The second light-emitting layer 152 and the second upper electrode 153 of the second light-emitting element ED2 positioned in each of the subpixels RSP, GSP, and BSP may be stacked on a partial area of the corresponding second lower electrode 151 exposed by the bank 116. Specifically, the second light-emitting layer 152 and the second upper electrode 153 may be stacked on the bank 116 and a partial area of the corresponding second lower electrode 151 exposed by the bank 116.

The second upper electrode 153 of each of the subpixels RSP, GSP, and BSP may be electrically connected to the first upper electrode 143 of each of the corresponding subpixels RSP, GSP, and BSP. For example, a voltage, which is applied to the second upper electrode 153 of the second light-emitting element ED2 positioned in each of the subpixels RSP, GSP, and BSP, may be equal to a voltage applied to the first upper electrode 143 of the first light-emitting element ED1 positioned in each of the corresponding subpixels RSP, GSP, and BSP. The second upper electrode 153 of each of the subpixels RSP, GSP, and BSP may include the same material as the first upper electrode 143 of each of the corresponding subpixels RSP, GSP, and BSP. For example, the second upper electrode 153 of each of the subpixels RSP, GSP, and BSP may be formed simultaneously with the first upper electrode 143 of each of the corresponding subpixels RSP, GSP, and BSP. The second upper electrode 153 of each of the subpixels RSP, GSP, and BSP may extend onto the bank 116 and be in direct contact with the first upper electrode 143 of each of the corresponding subpixels RSP, GSP, and BSP. The luminance of the first optical areas RWE, GWE, and BWE and the luminance of the second optical areas RNE, GNE, and BNE, which are positioned in the subpixels RSP, GSP, and BSP, may be controlled by a drive current generated in the corresponding subpixels RSP, GSP, and BSP.

The encapsulation member 180 may be positioned on the first and second light-emitting elements ED1 and ED2 of each of the subpixels RSP, GSP, and BSP. The encapsulation member 180 may suppress damage to the light-emitting elements ED1 and ED2 caused by moisture and impact from the outside. The encapsulation member 180 may have a multilayer structure. For example, the encapsulation member 180 may include a first encapsulation layer 181, a second encapsulation layer 182, and a third encapsulation layer 183 sequentially stacked. However, the present disclosure is not limited thereto.

The first encapsulation layer 181, the second encapsulation layer 182, and the third encapsulation layer 183 may include an insulating material. The second encapsulation layer 182 may include a material different from the material of the first encapsulation layer 181 and the third encapsulation layer 183. For example, the first encapsulation layer 181 and the third encapsulation layer 183 are inorganic encapsulation layers including an inorganic insulating material, and the second encapsulation layer 182 may include an organic encapsulation layer including an organic insulating material. Therefore, damage to the light-emitting elements ED1 and ED2 of the display device 100 caused by moisture and impact from the outside may be more effectively suppressed.

The black matrix 190 may be disposed on the encapsulation member 180. The black matrix 190 may be disposed between the plurality of subpixels RSP, GSP, and BSP to reduce a mixture of colors of the plurality of subpixels RSP, GSP, and BSP. Therefore, the black matrix 190 may be disposed to overlap the bank 116.

The touch insulation layer 117 may be disposed on the black matrix 190. The touch insulation layer 117 may be disposed between the encapsulation member 180, the black matrix 190, and the barrier layer 195 and configured to insulate the barrier layer 195.

The touch insulation layer 117 may include an insulating material. For example, the touch insulation layer 117 may include an organic insulating material or an inorganic insulating material. However, the present disclosure is not limited thereto.

The plurality of barrier layers 195 may be positioned on the touch insulation layer 117. The plurality of barrier layers 195 may be disposed above the first light-emitting element ED1 and the second light-emitting element ED2 in the display area.

The plurality of barrier layers 195 may restrict routes for light created by the first light-emitting element ED1 and the second light-emitting element ED2. For example, the plurality of barrier layers 195 may be disposed to overlap the edges of the first light-emitting areas RE1, GE1, and BE1 and the edges of the second light-emitting areas RE2, GE2, and BE2 and block light beams propagating in a lateral direction among the light beams emitted from the first light-emitting areas RE1, GE1, and BE1 and the second light-emitting areas RE2, GE2, and BE2. That is, the plurality of barrier layers 195, together with a first optical member 161 and a second optical member 162, may block light beams propagating in the lateral direction among the light beams emitted from the first optical areas RNE, GNE, and BNE positioned in the subpixels RSP, GSP, and BSP.

The plurality of barrier layers 195 may be made of the same material as the plurality of touch electrodes. For example, the plurality of barrier layers 195 may include a metallic material such as titanium (Ti), aluminum (Al), silver (Ag), copper (Cu), or a magnesium-silver alloy (Mg:Ag). However, the present disclosure is not limited thereto.

Meanwhile, a touch buffer layer may be further disposed between the encapsulation member 180 and the barrier layer 195. However, the present disclosure is not limited thereto. Although not illustrated in the drawings, the plurality of touch electrodes may be disposed on the touch insulation layer. The plurality of touch electrodes may be disposed on the touch insulation layer 117 and spaced apart from one another. The plurality of touch electrodes may be configured to sense a touch input applied from the outside by a user's finger, a touch pen, or the like. In addition, a touch bridge electrode may also be disposed on the encapsulation member 180 in addition to the barrier layer 195. However, the present disclosure is not limited thereto.

The first optical member 161 and the second optical member 162 may be disposed on the touch insulation layer 117.

The first optical member 161 and the second optical member 162 may be disposed on the touch insulation layer 117 and disposed on the same layer as the plurality of barrier layers 195. For example, the first optical member 161 and the second optical member 162 may be disposed to cover edges of the plurality of barrier layers 195.

The first optical member 161 may be disposed on the first light-emitting element ED1. The light created by the first light-emitting element ED1 of each of the subpixels RSP, GSP, and BSP is refracted by the first optical member 161 disposed in each of the first optical areas RWE, GWE, and BWE of the corresponding subpixels RSP, GSP, and BSP, and the light is discharged.

The first optical member 161 has a shape that does not restrict the propagation of the light in at least one side direction. In the present disclosure, a planar shape of the first optical member 161 positioned in each of the subpixels RSP, GSP, and BSP is a shape extending in the first direction X. For example, the planar shape of the first optical member 161 positioned in each of the subpixels RSP, GSP, and BSP is a bar shape extending in the first direction X. Therefore, the planar shape of the first optical member 161 may include a long side extending in the first direction X, and a short side extending from two opposite ends of the long side in the second direction Y. For example, the planar shape of the first optical member 161 may be a rectangular shape having the long side placed in the first direction X. In this case, the propagation direction of the light emitted from the first optical areas RWE, GWE, and BWE of the subpixels RSP, GSP, and BSP is not limited to the first direction X. For example, the content (or images) provided through the first optical areas RWE, GWE, and BWE of the subpixels RSP, GSP, and BSP may be shared with surrounding people adjacent to the user in the first direction X. Therefore, the content, which is provided by the light emitted through the first optical member 161, may be provided at a larger viewing angle in the first direction X than the content provided by the light emitted through the second optical member 162. For example, the content, which is provided by the light emitted through the first optical member 161, may be provided in a wide visual field mode (share mode).

At least a part of a top surface of a cross-sectional shape made by cutting the first optical member 161 in the first direction X may be flat. In addition, two opposite surfaces of the first optical member 161 may be formed to be curved or straight. For example, a cross-sectional shape based on the long side of the first optical member 161 may have a flat surface of an upper portion, and straight lines perpendicularly extending from two opposite ends of the flat surface toward the touch insulation layer 117. Alternatively, the cross-sectional shape based on the long side of the first optical member 161 may have a flat surface of an upper portion, and curved lines extending from two opposite ends of the flat surface toward the touch insulation layer 117.

The second optical member 162 may be disposed on the second light-emitting element ED2. The light created by the second light-emitting element ED2 of each of the subpixels RSP, GSP, and BSP is refracted by the second optical member 162 disposed in each of the second optical areas RNE, GNE, and BNE of the corresponding subpixels RSP, GSP, and BSP, and the light is discharged. The second optical member 162 may restrict the propagation of the light, which passes through the second optical member 162, in the first direction X. Further, the second optical member 162 may not restrict the propagation of the light, which passes through the second optical member 162, in the second direction Y. In the present disclosure, a planar shape of the second optical member 162 positioned in each of the subpixels RSP, GSP, and BSP is a shape extending in the second direction Y. For example, the planar shape of the second optical member 162 positioned in each of the subpixels RSP, GSP, and BSP may be a bar or elliptical shape extending in the second direction Y. Therefore, a maximum width of the planar shape of the second optical member 162 in the first direction X may be smaller than a maximum thickness in the second direction Y. Therefore, the planar shape of the second optical member 162 may include a major axis extending in the second direction Y, and a minor axis extending in the first direction X.

In this case, the propagation in the first direction X of the light emitted from the second optical areas RNE, GNE, and BNE of the subpixels RSP, GSP, and BSP may be restricted. For example, the content (or images) provided by the second optical areas RNE, GNE, and BNE of the subpixels RSP, GSP, and BSP may not be shared with surrounding people adjacent to the user. Therefore, the content, which is provided by the light emitted through the second optical member 162, may be provided at a smaller viewing angle in a leftward/rightward direction than the content provided by the light emitted through the first optical member 161. For example, the content, which is provided by the light emitted through the second optical member 162, may be provided in a narrow visual field mode (private mode).

A cross-sectional shape made by cutting the second optical member 162 in the first direction X may be formed only in curved shapes. Specifically, a cross-sectional shape of the second optical member 162 in the first direction X may be a shape in which a central portion thereof is convex upward. For example, the cross-sectional shape of the second optical member 162 in the first direction X may be a semicircular shape. However, the present disclosure is not limited thereto. In the cross-sectional shape of the second optical member 162 in the first direction X, a maximum width and a maximum thickness may be equal to or different from each other.

Meanwhile, the cross-sectional shape made by cutting the second optical member 162 in the second direction Y may be formed only in curved shapes and convex upward. For example, the cross-sectional shape of the second optical member 162 in the second direction Y may be a semi-elliptical shape in which a central portion thereof is convex upward. In this case, a thickness of the central portion of the second optical member 162 may be smaller than the maximum width. A maximum height of the second optical member 162 may be largest at a center of a width of the second optical member 162. However, the present disclosure is not limited thereto.

In the present disclosure, the first optical member 161 and the second optical member 162 may have shapes extending different directions. Specifically, the first optical member 161 has a shape extending in the first direction X, and the second optical member 162 has a shape extending in the second direction Y. In this case, the first direction X may refer to a horizontal direction in a plan view, i.e., the leftward/rightward direction. In addition, the second direction Y may refer to a vertical direction in a plan view, i.e., the upward/downward direction. For example, the first direction X and the second direction Y may be directions orthogonal to each other.

The first light-emitting areas RE1, GE1, and BE1 of the pixel PX may each have a shape corresponding to the first optical member 161 of each of the corresponding subpixels RSP, GSP, and BSP. For example, a planar shape of each of the first light-emitting areas RE1, GE1, and BE1 of the subpixels RSP, GSP, and BSP may be a shape extending in the first direction X. Specifically, the first light-emitting areas RE1, GE1, and BE1 may each have a bar shape extending in the first direction X. The first optical member 161 may have a larger size than each of the first light-emitting areas RE1, GE1, and BE1 of the corresponding subpixels RSP, GSP, and BSP. Therefore, it is possible to improve the efficiency of the light emitted from the first light-emitting areas RE1, GE1, and BE1 of the subpixels RSP, GSP, and BSP.

The second light-emitting areas RE2, GE2, and BE2 of the subpixels RSP, GSP, and BSP may each have a shape corresponding to the second optical member 162 of each of the corresponding subpixels RSP, GSP, and BSP. For example, a planar shape of each of the second light-emitting areas RE2, GE2, and BE2 of the subpixels RSP, GSP, and BSP may be a shape extending in the second direction Y. Specifically, the second light-emitting areas RE2, GE2, and BE2 may each have an elliptical or bar shape extending in the second direction Y. The second optical member 162 may have a larger size than each of the second light-emitting areas RE2, GE2, and BE2 of the corresponding subpixels RSP, GSP, and BSP. Therefore, it is possible to improve the efficiency of the light emitted from the second light-emitting areas RE2, GE2, and BE2 of the subpixels RSP, GSP, and BSP. The number of first light-emitting areas RE1, GE1, and BE1 or the number of second light-emitting areas RE2, GE2, and BE2 may vary for each of the subpixels RSP, GSP, and BSP. For example, the number of second light-emitting areas GE2 defined in the second optical area GNE of the second subpixel GSP and the number of second light-emitting areas BE2 defined in the second optical area BNE of the third subpixel BSP may each be larger than the number of second light-emitting areas RE2 defined in the second optical area RNE of the first subpixel RSP. In this case, the efficiency deviation between the second light-emitting elements ED2 positioned in the second optical areas RNE, GNE, and BNE may be compensated by the number of second light-emitting areas RE2, GE2, and BE2 defined in the second optical areas RNE, GNE, and BNE of the subpixels RSP, GSP, and BSP.

The optical member protective film 170 may be positioned on the first optical member 161 and the second optical member 162 of each of the subpixels RSP, GSP, and BSP. The optical member protective film 170 may include an insulating material. For example, the optical member protective film 170 may include an organic insulating material. A refractive index of the optical member protective film 170 may be smaller than a refractive index of the first optical member 161 and a refractive index of the second optical member 162 positioned in each of the subpixels RSP, GSP, and BSP. Therefore, in the display device 100 according to the embodiment of the present disclosure, the light, which has passed through the first optical member 161 and the second optical member 162 of each of the subpixels RSP, GSP, and BSP, may not be reflected toward the substrate 110 because of a difference in the refractive index from the optical member protective film 170.

Meanwhile, in case that the display device 100 according to the embodiment of the present disclosure is disposed in at least a part of the dashboard of the vehicle described with reference to FIG. 1 and provides the content to the user, e.g., the fellow passenger, the display device 100 may hinder the driver from driving of the vehicle. Therefore, the driver does not need to recognize the corresponding content. Therefore, it is necessary to restrict a visual field of an image disposed on the display device 100 disposed at a position facing a passenger seat while the vehicle travels in accordance with the user's requirement.

Therefore, the subpixels RSP, GSP, and BSP of the display device 100 according to the embodiment of the present disclosure each include the first and second optical members 161 and 162 having shapes extending in different directions. In addition, the first and second light-emitting elements ED1 and ED2, which respectively overlap the first and second optical members 161 and 162, may operate in different modes in accordance with the user's requirement.

Specifically, the first optical member 161 has the shape extending in the first direction X, such that the first light-emitting areas RE1, GE1, and BE1 may each be formed to have the shape extending in the first direction X. That is, in the first mode in which the first light-emitting areas RE1, GE1, and BE1 operate, both the fellow passenger and the driver may recognize images.

In contrast, the second optical member 162 has a shape extending in the second direction Y. That is, a width of the second optical member 162 in the first direction X is smaller than a width of the second optical member 162 in the second direction Y. Therefore, the second light-emitting areas RE2, GE2, and BE2 each have a small width in the first direction X. Therefore, in the second mode in which the second light-emitting element ED2 operates, it is possible to restrict diffusion of the light, which is emitted from the second light-emitting element ED2, in the first direction X, i.e., the leftward/rightward direction by the second optical member 162. Therefore, in the second mode, only the fellow passenger seated to face a front surface of the display device 100 may recognize images, whereas the driver may not recognize the images.

The second optical member 162 of the display device 100 according to the embodiment of the present disclosure has a shape extending in the upward/downward direction. Therefore, the second light-emitting areas RE2, GE2, and BE2 may each also have a shape extending in the upward/downward direction. Therefore, in the second mode in which the fellow passenger recognizes the image, the light emitted from the second light-emitting element ED2 may more widely propagate in the second direction Y, i.e., the upward/downward direction. Therefore, the display device 100 according to the embodiment of the present disclosure may ensure a wider viewing angle in the upward/downward direction. Therefore, it is possible to reduce a luminance deviation caused by a difference between heights of eyes changed by a body condition of the fellow passenger. Therefore, the fellow passenger may recognize high-quality images regardless of a change in viewing angles caused by a difference between the heights of the eyes.

In addition, in the display device 100 according to the embodiment of the present disclosure, the second optical member 162 has the shape extending in the second direction Y, such that the second light-emitting areas RE2, GE2, and BE2 may also extend in the second direction Y. Therefore, the second light-emitting areas RE2, GE2, and BE2 may further expand in the second direction Y. As described above, because the second light-emitting areas RE2, GE2, and BE2 expand, the luminous efficiency of the second light-emitting element ED2 may be improved. Therefore, it is possible to implement high-quality images with lower electric power.

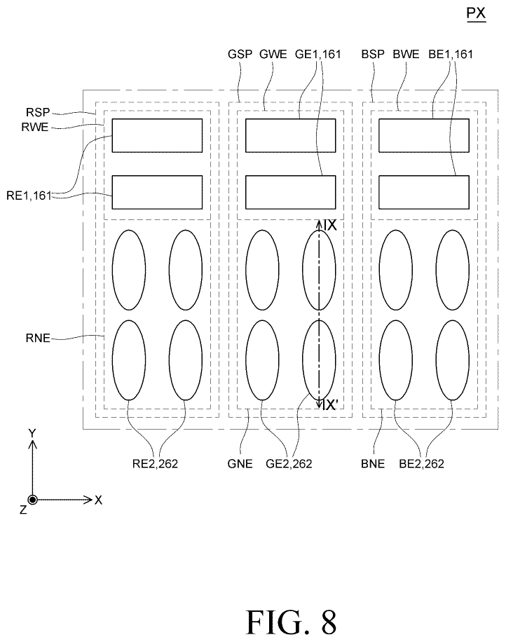

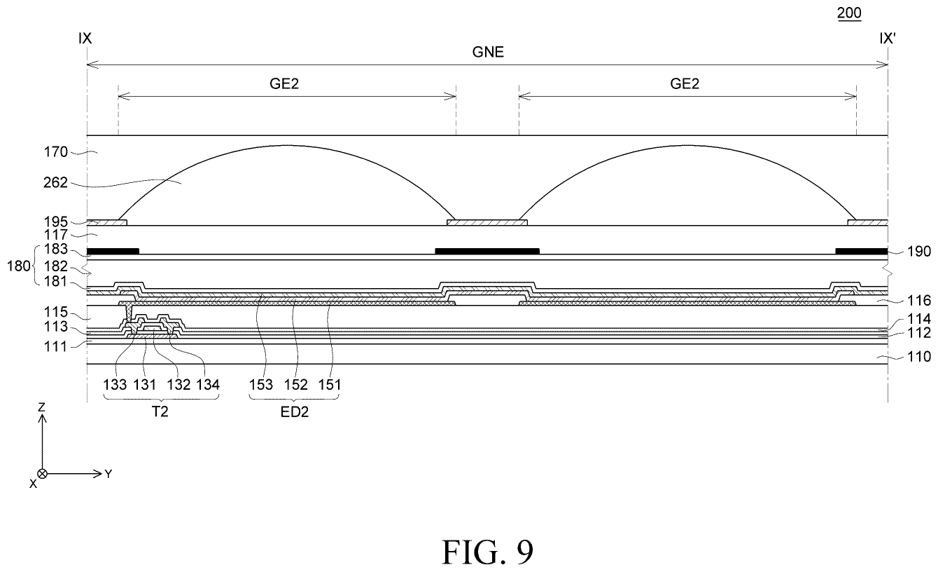

FIG. 8 is an enlarged top plan view illustrating a disposition of an optical member included in a display device according to another embodiment of the present disclosure. FIG. 9 is a cross-sectional view illustrating an example taken along line IX-IX′ in FIG. 8.

A display device 200 in FIGS. 8 and 9 is substantially identical in configuration to the display device 100 in FIGS. 4 to 7, except for a planar disposition of a second optical member 262. Therefore, repeated descriptions of the identical components will be omitted.

With reference to FIGS. 8 and 9 together, in the display device 200 according to another embodiment of the present disclosure, the plurality of second optical members 262 may be disposed in the second optical areas RNE, GNE, and BNE. For example, the second optical member 262 may be disposed in a plurality of rows and a plurality of columns in the second optical areas RNE, GNE, and BNE. In addition, the second optical members 262 may be spaced apart from one another.

In this case, the second optical members 262 adjacent to one another in the first direction X may be disposed in the same row. For example, the second optical members 262 adjacent to one another in the first direction X may be disposed to be positioned on the same straight line based on centers thereof. However, the present disclosure is not limited thereto. In another example, the centers of the second optical members 262 adjacent to one another in the first direction X may not be positioned on the same straight line.

In addition, the second optical members 262 adjacent to one another in the second direction Y may be disposed on the same column. For example, the centers of the second optical members 262 adjacent to one another in the second direction Y may be disposed to be positioned on the same straight line. However, the present disclosure is not limited thereto. In another example, the centers of the second optical members 262 adjacent to one another in the second direction Y may not be positioned on the same straight line.

Two or more second optical members 262 may be disposed in one row in each of the second optical areas RNE, GNE, and BNE. In addition, two or more second optical members 262 may be disposed in one column.

The display device 200 according to another embodiment of the present disclosure may include the first and second optical members 161 and 162 having the shapes extending in different directions in each of the subpixels RSP, GSP, and BSP, such that the display device 200 may operate in different modes in accordance with the user's requirement.

Specifically, the first optical member 161 has the shape extending in the first direction X, such that the first mode in which both the driver and the fellow passenger recognize images may be operated.

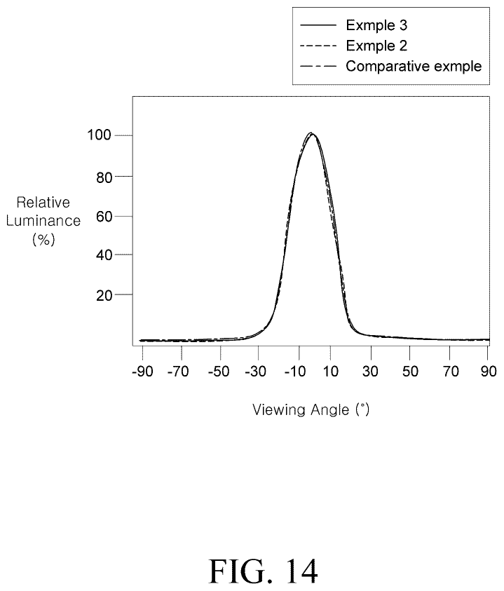

Meanwhile, FIG. 14 is a graph for explaining relative luminance in accordance with viewing angles in the leftward/rightward direction of display devices according to Examples of the present disclosure and Comparative Example. With reference to FIG. 14, the width of the first optical member 161 in the leftward/rightward direction is small, such that the second optical member 262 may restrict diffusion of the light in the first direction X from the second light-emitting element ED2. Therefore, the display device 200 may have a small viewing angle in the leftward/rightward direction. With reference to FIG. 14, both the display device according to Comparative Example, in which the planar shape of the second optical member is a circular shape, and the display device 200 according to another embodiment of the present disclosure (Example 2) have small widths in the leftward/rightward direction, such that both the display device of Comparative Example and the display device 200 of another embodiment of the present disclosure (Example 2) may have small viewing angles in the leftward/rightward direction. Therefore, the display device 200 may operate in the second mode in which only the fellow passenger recognizes images, and the driver does not recognize the images.

In addition, the second optical member 262 of the display device 200 according to another embodiment of the present disclosure has a shape extending in the upward/downward direction. Therefore, in the second mode of the display device 200 in which the fellow passenger recognizes the image, the light emitted from the second light-emitting element ED2 may more widely propagate in the upward/downward direction.

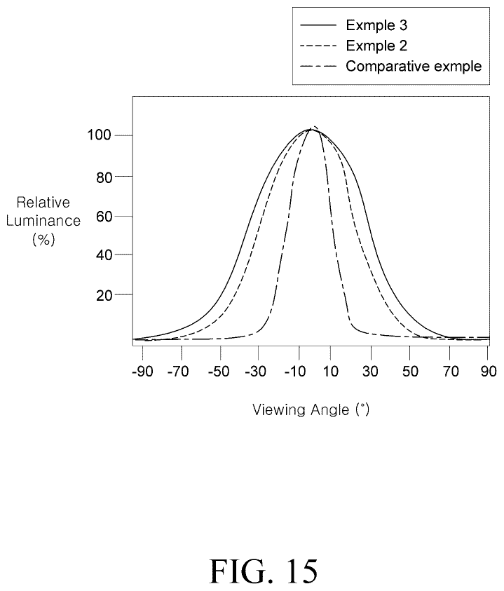

Meanwhile, FIG. 15 is a graph for explaining relative luminance in accordance with viewing angles in an upward/downward direction of the display devices according to Examples of the present disclosure and Comparative Example. With reference to FIG. 15, in comparison with Comparative Example in which the planar shape of the second optical member is a circular shape, the second optical member 262 of the display device 200 according to another embodiment of the present disclosure (Example 2) further extends long in the upward/downward direction in a plan view, such that the viewing angle in the upward/downward direction may be further increased. Therefore, it is possible to further reduce a luminance deviation caused by a difference between the heights of the eyes changed by the body condition of the fellow passenger.

In the display device 200 according to another embodiment of the present disclosure, the second optical members 262 may be disposed in the plurality of rows and the plurality of columns. Therefore, the second light-emitting elements ED2 disposed to correspond to the second optical members 262 may also be disposed in the plurality of rows and the plurality of columns. Therefore, a large number of second light-emitting elements ED2 and a large number of second optical members 262 are disposed in the second optical areas RNE, GNE, and BNE, such that the luminous efficiency of the second light-emitting element ED2 may be further improved. Therefore, it is possible to implement high-quality images with lower electric power.

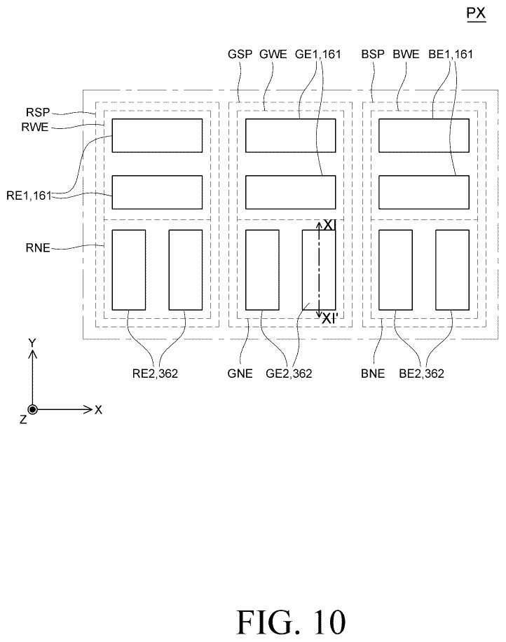

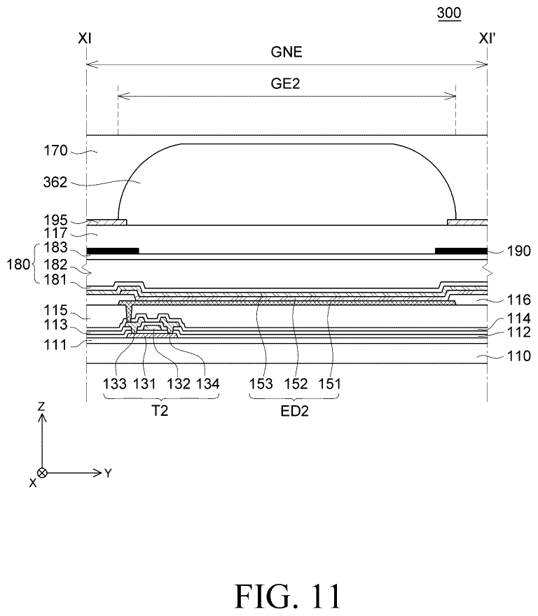

FIG. 10 is an enlarged top plan view illustrating a disposition of an optical member included in a display device according to still another embodiment of the present disclosure. FIG. 11 is a cross-sectional view illustrating an example taken along line XI-XI′ in FIG. 10.

A display device 300 in FIGS. 10 and 11 is substantially identical in configuration to the display device 100 in FIGS. 1 to 7, except for a planar shape and a cross-sectional shape of a second optical member 362. Therefore, repeated descriptions of the identical components will be omitted.

With reference to FIG. 10, in the display device 300 according to still another embodiment of the present disclosure, a planar shape of the second optical member 362 may be a bar shape extending in the second direction Y. Therefore, the planar shape of the second optical member 362 may include a long side extending in the second direction Y, and a short side extending from two opposite ends of the long side in the first direction X. For example, the planar shape of the second optical member 362 may be a rectangular shape having the long side placed in the second direction Y.

The plurality of second optical members 362 may be disposed in the subpixels RSP, GSP, and BSP. The plurality of second optical members 362 disposed in the subpixels RSP, GSP, and BSP may be spaced apart from one another in the first direction X in a plan view. For example, in case that two second optical members 362 are disposed in the second optical area RNE of the first subpixel RSP, the plurality of second optical members 362 may be disposed to be spaced apart from each other on a straight line extending in the first direction X. In this case, in the subpixels RSP, GSP, and BSP, the plurality of second optical members 362 may overlap one another in the first direction X. However, the present disclosure is not limited thereto.

With reference to FIG. 11, at least a part of a top surface of a cross-sectional shape made by cutting the second optical member 362 in the second direction Y may be flat. In addition, two opposite surfaces of the second optical member 362 may be formed to be curved or straight. For example, a cross-sectional shape based on the long side of the second optical member 362 may have a flat surface of an upper portion, and straight lines perpendicularly extending from two opposite ends of the flat surface toward the touch insulation layer 117. Alternatively, the cross-sectional shape based on the long side of the second optical member 362 may have a flat surface of an upper portion, and curved lines extending from two opposite ends of the flat surface toward the touch insulation layer 117.

The display device 300 according to still another embodiment of the present disclosure may include the first and second optical members 161 and 362 having the shapes extending in different directions in each of the subpixels RSP, GSP, and BSP, such that the display device 300 may operate in different modes in accordance with the user's requirement.

Specifically, the first optical member 161 has the shape extending in the first direction X, such that the first mode in which both the driver and the fellow passenger recognize images may be operated. In contrast, with reference to FIG. 14, the width of the first optical member 161 in the leftward/rightward direction is small, such that the viewing angle of the second optical member 362 in the leftward/rightward direction may be small. With reference to FIG. 14, both the display device according to Comparative Example, in which the planar shape of the second optical member is a circular shape, and the display device 300 according to still another embodiment of the present disclosure (Example 3) have small widths in the leftward/rightward direction, such that both the display device of Comparative Example and the display device 300 of still another embodiment of the present disclosure (Example 3) may have small viewing angles in the leftward/rightward direction. Therefore, the display device 300 may operate in the second mode in which only the fellow passenger recognizes images, and the driver does not recognize the images.

In addition, the second optical member 362 of the display device 300 according to still another embodiment of the present disclosure has a shape extending in the upward/downward direction. Therefore, in the second mode of the display device 300 in which the fellow passenger recognizes the image, the light emitted from the second light-emitting element ED2 may more widely propagate in the upward/downward direction. With reference to FIG. 15, in comparison with Comparative Example in which the planar shape of the second optical member is a circular shape, the second optical member 362 of the display device 300 according to still another embodiment of the present disclosure (Example 3) further extends long in the upward/downward direction in a plan view, such that the viewing angle in the upward/downward direction may be further increased. Therefore, it is possible to further reduce a luminance deviation caused by a difference between the heights of the eyes changed by the body condition of the fellow passenger.

Further, widths of upper and lower distal ends of the display device 300 (Example 3), in which the planar shape of the second optical member 362 is a bar shape, may be increased in comparison with the display device 200 (Example 2) in which the planar shape is an elliptical shape. Therefore, in the display device 300 (Example 3) in which the planar shape of the second optical member 362 is a bar shape, the viewing angle in the upward/downward direction may further expand. Therefore, it is possible to further reduce a luminance deviation caused by a difference between the heights of the eyes of the fellow passenger.

In addition, in the display device 300 according to still another embodiment of the present disclosure, the second optical member 362 has the shape extending in the second direction Y, such that the second light-emitting areas RE2, GE2, and BE2 may also extend in the second direction Y. Therefore, the luminous efficiency of the second light-emitting element ED2 may be improved, and high-quality images may be implemented by lower electric power.

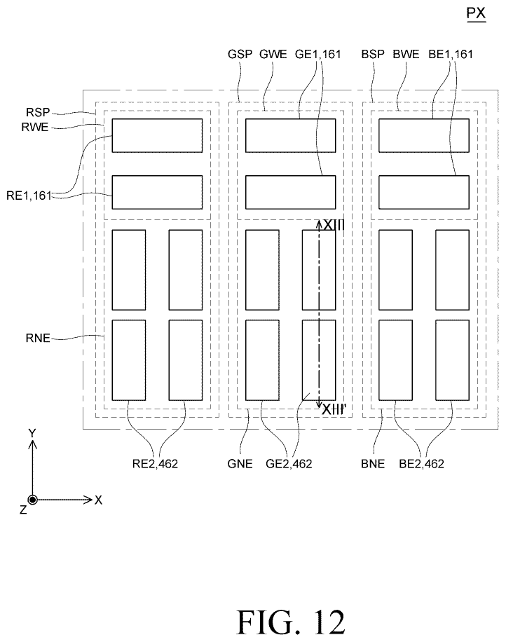

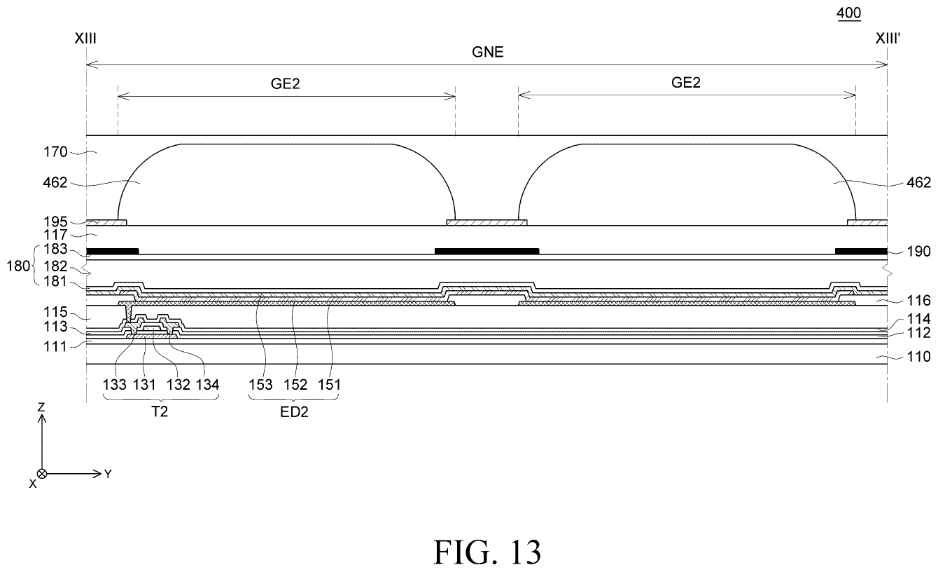

FIG. 12 is an enlarged top plan view illustrating a disposition of an optical member included in a display device according to yet another embodiment of the present disclosure. FIG. 13 is a cross-sectional view illustrating an example taken along line XIII-XIII′ in FIG. 12.

A display device 400 in FIGS. 12 and 13 is substantially identical in configuration to the display device 300 in FIGS. 10 and 11, except for a planar disposition of a second optical member 462. Therefore, repeated descriptions of the identical components will be omitted.

With reference to FIGS. 12 and 13 together, in the display device 400 according to yet another embodiment of the present disclosure, the plurality of second optical members 462 may be disposed in the second optical areas RNE, GNE, and BNE. For example, the second optical member 462 may be disposed in a plurality of rows and a plurality of columns in the second optical areas RNE, GNE, and BNE. In addition, the second optical members 462 may be spaced apart from one another.

In this case, the second optical members 462 adjacent to one another in the first direction X may be disposed in the same row. For example, the second optical members 462 adjacent to one another in the first direction X may be disposed to be positioned on the same straight line based on centers thereof. However, the present disclosure is not limited thereto. In another example, the centers of the second optical members 462 adjacent to one another in the first direction X may not be positioned on the same straight line.

In addition, the second optical members 462 adjacent to one another in the second direction Y may be disposed on the same column. For example, the centers of the second optical members 462 adjacent to one another in the second direction Y may be disposed to be positioned on the same straight line. However, the present disclosure is not limited thereto. In another example, the centers of the second optical members 462 adjacent to one another in the second direction Y may not be positioned on the same straight line.

Two or more second optical members 462 may be disposed in one row in each of the second optical areas RNE, GNE, and BNE. In addition, two or more second optical members 462 may be disposed in one column.

The display device 400 according to yet another embodiment of the present disclosure may include the first and second optical members 161 and 462 having the shapes extending in different directions in each of the subpixels RSP, GSP, and BSP, such that the display device 400 may operate in different modes in accordance with the user's requirement.

Specifically, the first optical member 161 has the shape extending in the first direction X, such that the first mode in which both the driver and the fellow passenger recognize images may be operated. In addition, the width of the first optical member 161 in the leftward/rightward direction is smaller, such that the second optical member 462 may restrict diffusion of the light in the first direction X from the second light-emitting element ED2. Therefore, the display device 400 may have a small viewing angle in the leftward/rightward direction. Therefore, the display device 400 may operate in the second mode in which only the fellow passenger recognizes images, and the driver does not recognize the images.

In addition, the second optical member 462 of the display device 400 according to yet another embodiment of the present disclosure has a shape extending in the upward/downward direction. Therefore, in the second mode of the display device 400 in which the fellow passenger recognizes the image, the light emitted from the second light-emitting element ED2 may more widely propagate in the upward/downward direction, such that the viewing angle in the upward/downward direction may be further increased. Therefore, it is possible to further reduce a luminance deviation caused by a difference between the heights of the eyes changed by the body condition of the fellow passenger.

In the display device 400 according to yet another embodiment of the present disclosure, the second optical members 462 may be disposed in the plurality of rows and the plurality of columns. Therefore, the second light-emitting elements ED2 disposed to correspond to the second optical members 462 may also be disposed in the plurality of rows and the plurality of columns. Therefore, a large number of second light-emitting elements ED2 and a large number of second optical members 462 are disposed in the second optical areas RNE, GNE, and BNE, such that the luminous efficiency of the second light-emitting element ED2 may be further improved. Therefore, it is possible to implement high-quality images with lower electric power.

The exemplary embodiments of the present disclosure can also be described as follows:

A display device according to an embodiment of the present disclosure comprise a substrate, a first light-emitting element disposed on the substrate a first optical member configured to refract light emitted from the first light-emitting element, the first optical member having a planar shape that is a shape extending in a first direction, a second light-emitting element disposed on the substrate and configured to emit light with the same color as the light from the first light-emitting element, and a second optical member configured to refract light emitted from the second light-emitting element, the second optical member having a planar shape that is a shape extending in a second direction different from the first direction.

The first direction and the second direction may be orthogonal to each other.

The planar shape of the first optical member may be a bar shape extending in the first direction, and the planar shape of the second optical member may be a bar or elliptical shape extending in the second direction.

When the planar shape of the second optical member is an elliptical shape, a cross-sectional shape of the second optical member based on a major axis of the second optical member may be a semi-elliptical shape, and a cross-sectional shape of the second optical member based on a minor axis of the second optical member may be a semicircular shape.

When the planar shape of the second optical member is a bar shape, at least a part of a cross-sectional shape of the second optical member based on a long side of the second optical member may include a straight edge, and a cross-sectional shape of the second optical member based on a short side of the second optical member may be a semicircular shape.

The first optical member may be provided as a plurality of first optical members, and the plurality of first optical members may be disposed in the same column in a plan view and spaced apart from one another.

Wherein the second optical member may be provided as a plurality of second optical members, and the plurality of second optical members may be disposed in the same row in a plan view and spaced apart from one another.

The plurality of second optical members may be provided in a plurality of rows and a plurality of columns and may be disposed to be spaced apart from one another.

The display device may further comprise a subpixel circuit disposed on the substrate and electrically connected to the first light-emitting element and the second light-emitting element, wherein the subpixel circuit may selectively operate one of the first light-emitting element and the second light-emitting element.

The display device according to an another embodiment of the present application comprises a plurality of subpixels, wherein each of the plurality of subpixels include first and second light-emitting elements emitting light with the same color, a first optical member disposed on the first light-emitting element, configured to overlap the first light-emitting element, and disposed to extend in a horizontal direction in a plan view, a second optical member disposed on the second light-emitting element, configured to overlap the second light-emitting element, and disposed to extend in a vertical direction in a plan view, and a subpixel circuit electrically connected to the first and second light-emitting elements and configured to selectively operate at least one of the first and second light-emitting elements.

A planar shape of the first optical member may be a rectangular shape, and a planar shape of the second optical member may be an elliptical shape.

A cross-sectional shape of the second optical member based on a major axis of the second optical member and a cross-sectional shape of the second optical member based on a minor axis may be curved shapes.

Planar shapes of the first and second optical members may be rectangular shapes.

At least a part of a top of a cross-sectional shape of the second optical member based on a long side of the second optical member may include a straight edge, and a cross-sectional shape of the second optical member based on a short side of the second optical member is formed in a curved shape.

The first optical member may be provided as a plurality of first optical members spaced apart from one another in the vertical direction, the second optical member may be provided as a plurality of second optical members spaced apart from one another in the horizontal direction, and the plurality of first optical members and the plurality of second optical members at least partially overlap one another in the vertical direction.

The first optical member may be provided as a plurality of first optical members spaced apart from one another in the vertical direction, the second optical member may be provided as a plurality of second optical members spaced apart from one another in the vertical direction and the horizontal direction, and the plurality of first optical members and the plurality of second optical members at least partially overlap one another in the vertical direction.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. These and other changes can be made to the embodiments in light of the above-detailed

description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate;
a first light-emitting element on the substrate;
a first optical member configured to refract light emitted from the first light-emitting element, the first optical member having a planar shape that is a shape extending in a first direction;
a second light-emitting element on the substrate and configured to emit light with a same color as the light from the first light-emitting element; and
a second optical member configured to refract light emitted from the second light-emitting element, the second optical member having a planar shape that is a shape extending in a second direction different from the first direction.

2. The display device of claim 1, wherein the first direction and the second direction are transverse to each other.

3. The display device of claim 1, wherein the planar shape of the first optical member is a bar shape extending in the first direction, and the planar shape of the second optical member is a bar or elliptical shape extending in the second direction.

4. The display device of claim 3, wherein when the planar shape of the second optical member is an elliptical shape, a cross-sectional shape of the second optical member based on a major axis of the second optical member is a semi-elliptical shape, and a cross-sectional shape of the second optical member based on a minor axis of the second optical member is a semicircular shape.

5. The display device of claim 3, wherein when the planar shape of the second optical member is a bar shape, at least a part of a cross-sectional shape of the second optical member based on a long side of the second optical member includes a straight edge, and a cross-sectional shape of the second optical member based on a short side of the second optical member is a semicircular shape.

6. The display device of claim 1, wherein the first optical member is provided as a plurality of first optical members, and the plurality of first optical members are disposed in the same column in a plan view and spaced apart from one another.

7. The display device of claim 1, wherein the second optical member is provided as a plurality of second optical members, and the plurality of second optical members are disposed in the same row in a plan view and spaced apart from one another.

8. The display device of claim 7, wherein the plurality of second optical members are provided in a plurality of rows and a plurality of columns and disposed to be spaced apart from one another.

9. The display device of claim 1, further comprising:
a subpixel circuit on the substrate and electrically connected to the first light-emitting element and the second light-emitting element,
wherein the subpixel circuit is configured to selectively operate one of the first light-emitting element and the second light-emitting element.

10. A display device comprising:
a plurality of subpixels,
wherein each of the plurality of subpixels include first and second light-emitting elements emitting light with a same color;
a first optical member on the first light-emitting element, configured to overlap the first light-emitting element, and disposed to extend in a horizontal direction in a plan view;
a second optical member on the second light-emitting element, configured to overlap the second light-emitting element, and disposed to extend in a vertical direction in a plan view; and
a subpixel circuit electrically connected to the first and second light-emitting elements and configured to selectively operate at least one of the first and second light-emitting elements.

11. The display device of claim 10, wherein a planar shape of the first optical member is a rectangular shape, and a planar shape of the second optical member is an elliptical shape.

12. The display device of claim 11, wherein a cross-sectional shape of the second optical member based on a major axis of the second optical member and a cross-sectional shape of the second optical member based on a minor axis are curved shapes.

13. The display device of claim 10, wherein planar shapes of the first and second optical members are rectangular shapes.

14. The display device of claim 13, wherein at least a part of a top of a cross-sectional shape of the second optical member based on a long side of the second optical member includes a straight edge, and a cross-sectional shape of the second optical member based on a short side of the second optical member is formed in a curved shape.

15. The display device of claim 10, wherein the first optical member is provided as a plurality of first optical members spaced apart from one another in the vertical direction, the second optical member is provided as a plurality of second optical members spaced apart from one another in the horizontal direction, and the plurality of first optical members and the plurality of second optical members at least partially overlap one another in the vertical direction.

16. The display device of claim 10, wherein the first optical member is provided as a plurality of first optical members spaced apart from one another in the vertical direction, the second optical member is provided as a plurality of second optical members spaced apart from one another in the vertical direction and the horizontal direction, and the plurality of first optical members and the plurality of second optical members at least partially overlap one another in the vertical direction.

17. A display device comprising:
a display panel, extending in a first direction and a second direction different from the first direction, comprising a plurality of pixels;
wherein each subpixel of one of the plurality of pixels comprises:
a first light-emitting element;
a plurality of first optical members each of which is configured to refract light emitted from the first light-emitting element, and has a planar shape with a dimension in the first direction greater than a dimension in the second direction;
a second light-emitting element configured to emit light with the same color as the light from the first light-emitting element; and
a plurality of second optical members each of which is configured to refract light emitted from the second light-emitting element, and has a planar shape with a dimension in the first direction less than a dimension in the second direction.

18. The display device of claim 17, wherein a second optical member of the plurality is configured to limit a viewing angle in the first direction and allow a wider viewing angle in the second direction.

19. The display device of claim 17, wherein a second optical member of the plurality includes a curved surface that is convex in both a vertical and horizontal cross-sectional view.

20. The display device of claim 1, further comprising a black matrix disposed to overlap a boundary between the first optical member and the second optical member.
